(19) United States
(12) Patent Application Publication
(10) Pub. No.: US 2006/0018355 A1
(43) Pub. Date: Jan. 26, 2006

(54) Laser diode arrays with reduced heat induced strain and stress

(75) Inventors: Alfred Feitisch, Los Gatos, CA (US); Carsten Lindstroem, Haegerstern (SE); Peter Blixt, Haegerstern (SE)

Correspondence Address: HELLER EHRMAN LLP, 275 MIDDLEFIELD ROAD, MENLO PARK, CA, 94025-3506, US

(73) Assignee: ComLasc.NT-AB, Stockholm (SE)

(21) Appl. No.: 10/897,560

(22) Filed: Jul. 23, 2004

(51) Int. Cl. H01S 5/00

(52) U.S. Cl. 372/50.12

(57) ABSTRACT

A laser diode array has a semiconductor layered structure that includes at least one active layer. A heat sink is coupled to semiconductor layered structure. A plurality of laser emitters are formed in the active layer. A majority of the plurality of laser emitters have a spacing between adjacent laser emitters that provides for a more uniform heat distribution.

### BACKGROUND OF THE INVENTION

1. Field of the Invention

This invention relates generally to laser diode arrays, and more particularly to laser diode arrays that have a semiconductor and a heat sink and more uniform heat distribution in order to reduce heat induced strain and stress inside the semiconductor and between the semiconductor and the heat sink, reduce peak operating temperature inside the laser emitter and reduce broadening of the spectral emission.

2. Description of the Related Art

Laser diode array performance and reliability are being plagued by very high heat generation in the laser emitters, broad spectral emission and poor beam quality.

High operating power densities, high operating temperatures of laser emitters of these laser arrays and high temperature differentials between emitter area and non-emitter area significantly reduce reliability, operating life time, operating efficiency and maximum power capability of the laser diode array itself. To mitigate the negative consequences of high operating temperatures and high temperature differentials across laser emitters, these laser arrays are typically soldered p-side down with soft Indium metal directly to heat sinks such as thin-wall copper micro coolers, thus minimizing the heat resistance between the active laser emitter and the means of heat removal. This type of platform typically fails in industrial applications between only 4000 and 10,000 hours of operation, severely undermining the development of important applications such as pumping of kW class solid state lasers for automotive or electronic welding applications. In addition, broad spectral emission reduces overall efficiency in important applications such as pumping of solid state lasers.

Industry standard 10 mm laser arrays for applications such as pumping of solid state lasers typically have between 19 and 37 broad area laser emitters, 90 μm to 200 μm wide, which are widely spaced greater than 100 μm apart. Emitter size and spacing have been chosen to maximize output power while balancing life time penalties from high optical operating power densities and peak operating temperatures of the laser emitters and to facilitate coupling of each emitter into a separate optical fiber. Meeting all these constraints limits the maximum continues wave (cw) output power from a laser diode array and its reliability and life time.

Laser emitters on a laser diode array run hotter at the emitter center line compared to the edges of the emitter, accelerating power degradation in the hot center zones and broadening spectral emission. Wider emitters have hotter center line operating temperatures and greater center to edge temperature differentials than narrower emitters at the same optical power density. Typical 10 mm laser arrays can generate upwards of 100 W in waste heat in an area of roughly 10 mm×1.3 mm.

Attempting to mitigate undesirable consequences of high operating temperatures and temperature differentials such as spectral broadening, loss of operating efficiency and loss of reliability and life time, the industry has developed heat sinking and bonding schemes which attempt to improve heat removal from the laser emitters of such arrays. Most of these schemes use soft Indium metal to directly solder the p-side of the laser array to the surface of a heat sink, which is typically made from copper and is cooled by some means. The most efficient heat transfer schemes employ thin-wall copper micro coolers, with typical wall thicknesses of about 0.254 mm, which allow cooling liquid, typically water, to circulate very near to the heat generating laser emitters. Soft Indium solder needs to be employed to absorb the substantial differential thermal expansion between the laser diode array and the heat sink surface.

However, this heat sinking technology seriously limits the operating life time of the complete, practically useable, diode laser array platform. Especially in important applications such as pumping of kW class solid state lasers for automotive and electronic welding, these platforms typically fail between 4,000 and 10,000 hours of operation. Longer life times are primarily the result of lower operating powers of the diode laser arrays because lower powers generate less heat, stress and strain in the array and at its bonding interfaces.

One of the main failure modes is shearing and separation of the soft Indium solder, caused by frequent on/off cycling of the laser array, which is typical for welding applications. Separation of the solder joint will locally impede heat removal, overheat the laser array and cause its failure. A second class of failure modes is related to corrosion and erosion of the micro cooler walls and its internal structures. Any leak in the cooler wall constitutes a failure of the array. Erosion of internal structures, which guide the liquid flow to efficiently remove heat across the whole diode laser array surface, will lead to a change in flow patterns, localized overheating of the laser array, accelerated power degradation and premature failure. Blockage of the small channels inside the micro cooler can also cause insufficient cooling of the laser array and premature failure.

An example of a commercially available laser diode array is 10 mm wide, has 19, 25 or 37 emitters, which are evenly spaced and parallel to each other. Each emitter is 90 to 200 μm wide, operating in transverse and longitudinal multi-mode, typically generating 1-2 W optical power and 1.7 W to 3.5 W of waste heat. The laser emitter cavity length typically ranges from 0.6 mm to 1.3 mm. The height of the laser array, without its heat sink, is typically 100 μm to 140 μm. The laser array is soldered with soft Indium metal to a commercially available, so-called, copper micro-cooler, which contains narrow internal channels where de-ionized water flows under pressure to remove waste heat from the laser array. The use of a soft solder such as Indium metal is indispensable to prevent the greater thermal expansion of the cooler material, typically copper, to fracture the semiconductor substrate, typically GaAs, InP or GaN. The micro-cooler is connected via O-rings to external tubing providing water for heat removal. The diode bar has an electrical contact on its metallized top face and the micro-cooler serves as electrical ground.

One of the shortcomings of industry standard diode laser arrays with 90 μm to 200 μm emitter width, is that such highly transverse multimode emitters reduce focusability and depth of focus of the laser emission from each emitter. Lasers that oscillate in transverse multi-mode operation will have an angular broadening of the laser beam by \sqrt{N} where N is the number of transverse modes. The number N increases with the width of the laser emitter. The minimum spot size radius of the laser beam is also increased by \sqrt{N} and the spot size area is increased proportionally to N (see further A. Siegman, Lasers, University Science Books 1986, p. 695). This has large impact on applications where spot-size, beam divergence and depth of focus are crucial. An example of such an application is laser printing where spot sizes must be less than 10 μm. To achieve such spot size with highly multimode laser emission drastically reduces depth of focus and commercial viability of such an application.

Another shortcoming of current industry standard pump laser arrays for solid state laser pumping is that wavelength broadening causes manufacturing yield loss and raises cost for such diode laser arrays. Furthermore, spectral broadening of the pump laser diode array emission causes additional, undesirable performance limitations for the solid state laser and requires application of costly temperature control mechanisms to prevent wavelength shift of pump diode laser arrays.

Typical, crystalline solid state laser materials, of which Nd:YAG and Yb:YAG are critically important for commercial applications, generally have spectrally very narrow absorption line widths of just a few nm. Pump laser radiation outside the absorption window is therefore wasted, causing reduced operating efficiency and excessive waste heat inside the crystal, which in turn leads to thermal lensing and stress and strain inside the crystal. Thermal lensing and such internal stresses limit beam quality and maximum output power that can be obtained from such a solid state laser. Thermal gradients across the emitter are by far the largest contributor to spectral broadening of the typical wide area emitter diode laser array.

Finite element (FEM) simulations for a 135 μm emitter, 19 element, array, at 40 W operating power, which is typical for solid state laser pumping, show a temperature variation of ˜2.6° C. from centre to emitter edge.

FIG. 1 illustrates a temperature profile for a standard laser diode array, commercially available from Osram Optosemiconductors, Regensburg, Germany, with 25 emitters, having an emitter width of 200 μm and an emitter spacing of 200 μm The laser diode array in FIG. 2 has 19 emitters and is commercially available from Spectra-Physics Lasers, Mountain View, Calif. FIG. 2 is an FEM simulation of the temperature profile in the copper micro cooler top plate, beneath a 135 μm emitter which dissipates 3.15 W of waste heat. The peak temperature at the center line of the emitter increases by about 5.6° C. and the temperature at the edge of the emitter increases about 3° C. The thickness of the Cu plate is 256 μm (y-axis) and the emitter to emitter spacing is 365 μm (x-axis). Use of a non-micro cooler heat sink or of an intermediate, expansion matched copper-tungsten sub-mount would increase the maximum temperature, temperature differential and related wavelength broadening. The gain of typical AlInGaAs pump diode laser material shifts at a rate of 0.3 nm/° C., causing spectral broadening of 0.8 nm, in this case.

This spectral broadening constitutes a 40% increase of spectral emission width, assuming a non-broadened line width of 2 nm, which is typical for industry standard laser arrays made from AlInGaAs. Across the complete width of a diode laser array, there occurs an additional temperature gradient between the center emitter and emitters located at the edges, causing additional broadening of the emission across the width of the array. This broadening reduces any margin for offset and thermal shift of the central emission wavelength during diode laser array manufacturing and during operation on a solid state laser. This type of wavelength broadening is one of the major contributors to manufacturing yield loss for diode laser arrays and forces diode laser pumped solid state lasers to employ costly temperature control mechanisms to maintain pump diode laser array wavelength inside the laser crystal absorption band.

Another problem with current, industry standard diode laser arrays arises from solder voids between the laser array and its heat sink. Soldering a large bar of 10 mm×1.3 mm is not a trivial issue, especially not with Indium metal. One of the main difficulties is to mitigate voids in the solder used to attach the laser array to its respective heat sink. If such a void is located under a laser emitter, the emitter operating temperature will increase sharply, by 10ths of degrees, just above the void. As is known in the industry, this will drastically accelerate degradation of such laser emitter and further contribute to spectral broadening for such laser emitter. Enhanced degradation and power loss from localized overheating of the active laser emitter is especially pronounced for the present, industry standard laser arrays with wide area emitters which are bonded p-side (active side) down. Localized overheating inside a laser emitter can easily destroy the complete emitter, causing a sudden, premature power loss of the array between 2.7% and 5.3%, per each failing emitter. If this defect is detected during the manufacturing process it will result in yield loss and raise manufacturing cost. Otherwise, it will result in premature failure in its respective application, causing even greater loss and costs. There is no process known to solder absolutely void free across such a large area.

Another shortcoming of the present industry standard laser diode arrays is that such arrays with 19 to 37 emitters require some form of extraneous beam homogenization to generate a homogeneous intensity distribution of pump laser intensity, inside a solid state laser crystal or Disk if used for side pumping of such solid state lasers. Inhomogeneities of the pump diode laser array light intensity distribution inside the solid state laser crystal will cause localized thermal lensing and stress and strain problems inside the solid state laser crystal, which degrade solid state laser beam quality and output power. The wider the spacing of emitters and the wider the emitters of a pump laser diode array are, the more pronounced these problems become.

There is a need for improved laser diode arrays. There is a further need for laser diode arrays where the emitters have a spacing selected to provide for a more uniform heat distribution. There is yet a further need for laser diode arrays that have a more uniform heat distribution which reduces heat induced strain and stress between the semiconductor and the heat sink of the laser diode array. There is still a further need for laser diode arrays with spacings between emitters of no greater than 100 microns.

### SUMMARY OF THE INVENTION

Accordingly, an object of the present invention is to provide improved laser diode arrays.

Another object of the present invention is to provide laser diode arrays with improved reliability, optical beam homogeneity and spectral performance.

A further object of the present invention is to provide laser diode arrays with improved defect impact, power degradation and lower divergence of laser emitters.

Yet another object of the present invention is to provide laser diode arrays with reduced thermal gradients and hot-spots.

Yet another object of the present invention is to provide laser diode arrays with increased output power at the same thermal gradients and hot spot temperatures as industry standard laser arrays.

Another object of the present invention is to provide laser diode arrays where the emitters have a spacing selected to provide for a more uniform heat distribution.

A further object of the present invention is to provide laser diode arrays that have a more uniform heat distribution which reduces heat induced strain and stress between the semiconductor and the heat sink of the laser diode array.

Yet another object of the present invention is to provide laser diode arrays with spacings between emitters of no greater than 100 microns.

Yet another object of this invention is to provide laser diode arrays with variable spacings between emitters where at least two of the emitters have a spacing no greater than 100 microns.

Another object of the present invention is to provide laser diode arrays that have emitters with a width of 1 μm to 250 μm.

These and other objects of the present invention are achieved in a laser diode array with a semiconductor layered structure that includes at least one active layer. A heat sink is coupled to semiconductor layered structure. A plurality of laser emitters are formed in the active layer. A majority of the plurality of laser emitters have a spacing between adjacent laser emitters that provides for a more uniform heat distribution.

In another embodiment of the present invention, a laser diode array includes a layered semiconductor structure with at least one active layer. A heat sink is coupled to the layered semiconductor structure. A plurality of emitters are formed in the at least one active layer. At least a portion of the plurality of emitters have a spacing between adjacent laser emitters that is no greater than 50 microns.

In another embodiment of the present invention, a method of producing an output from a laser diode array provides a laser diode array that has a layered semiconductor structure, with at least one active layer, and a plurality of emitters formed in the at least one active layer. At least a portion of the laser emitters are positioned to have a spacing between adjacent laser emitters that provides a more uniform heat distribution. Heat is removed from the semiconductor with a heat sink. An output beam is produced.

### DESCRIPTION OF THE DRAWINGS

FIG. 1 illustrates a temperature profile across an emitter, in one embodiment of a commercially available laser diode array that has 25 emitters, an emitter width of 200 μm and an emitter spacing 200 μm.

FIG. 2 illustrates a temperature profile for a commercially available laser diode array with 19 emitters, an emitter width of 135 μm, and an emitter spacing of 365 μm.

FIG. 3(a) is a perspective view of one embodiment of a diode laser array of the present invention.

FIG. 3(b) is a cross-sectional view of FIG. 1(a).

FIG. 4 is a cross-sectional view of one embodiment of a diode laser array of the present invention showing the crystal mirror facets.

FIG. 5 is a cross-sectional view of one embodiment of a diode laser array of the present invention showing the angularity of the plane of crystal mirror facets.

FIG. 6(a) is a perspective view of one embodiment of a diode laser array of the present invention showing a heat sink and a p-doped metallzied surface.

FIG. 6(b) is a perspective view of one embodiment of a diode laser array of the present invention showing a heat sink and a n-doped metallzied surface.

FIG. 7 is a perspective view of one embodiment of a diode laser array of the present invention showing a bonding agent between the layered semiconductor structure and the heat sink.

FIG. 8(a) is a perspective view of one embodiment of a diode laser array of the present invention showing the layered semiconductor structure coupled to a submount with the p-doped metallized surface.

FIG. 8(b) is a perspective view of one embodiment of a diode laser array of the present invention showing the layered semiconductor structure coupled to a submount with the n-doped metallized surface.

FIG. 9(a) is a perspective view of one embodiment of a diode laser array of the present invention showing the layered semiconductor structure coupled with the p-doped metallized surface to a heat sink with a cooling channel.

FIG. 9(b) is a perspective view of one embodiment of a diode laser array of the present invention showing the layered semiconductor structure coupled with the n-doped metallized surface and a heat sink with a cooling channel.

FIG. 10(a) illustrates a temperature profile across an emitter, in one embodiment of a laser diode array of the present invention that has 400 emitters, an emitter width of 5 μm and an emitter spacing 20 μm.

FIG. 10(b) illustrates a temperature profile across an emitter, in one embodiment of a laser diode array of the present invention that has 250 emitters, an emitter width of 20 μm and an emitter spacing 20 μm.

FIG. 10(c) illustrates a temperature profile across an emitter, in one embodiment of a laser diode array of the present invention that has 100 emitters, an emitter width of 50 μm and an emitter spacing 50 μm.

FIG. 10(d) illustrates a temperature profile across an emitter, in one embodiment of a laser diode array of the present invention that has 50 emitters, an emitter width of 100 μm and an emitter spacing 100 μm.

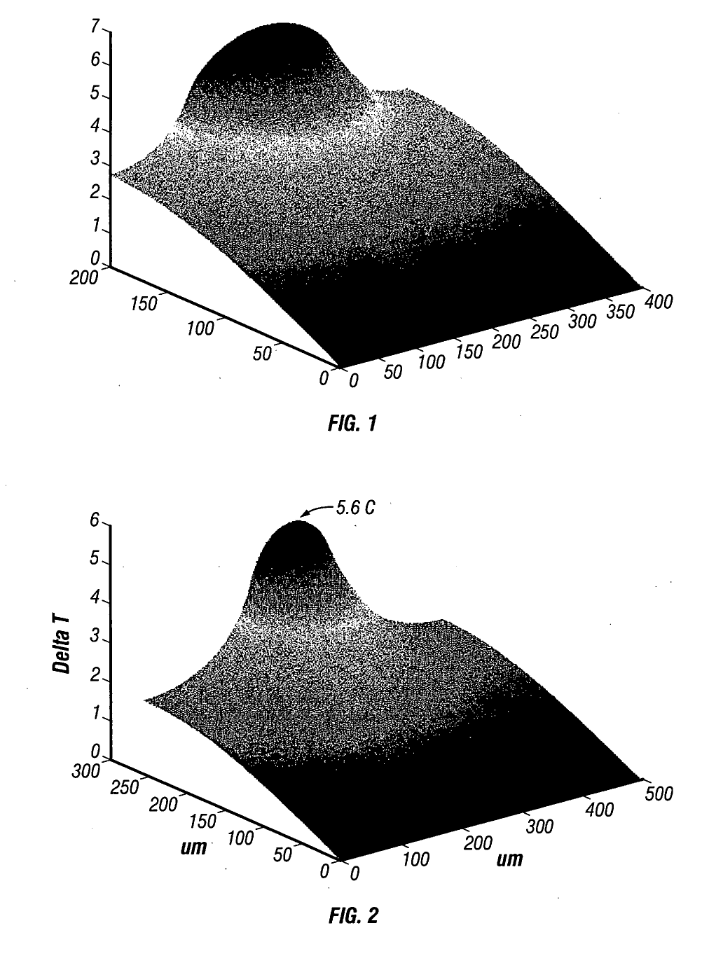

### DETAILED DESCRIPTION OF THE PREFERRED EMBODIMENTS

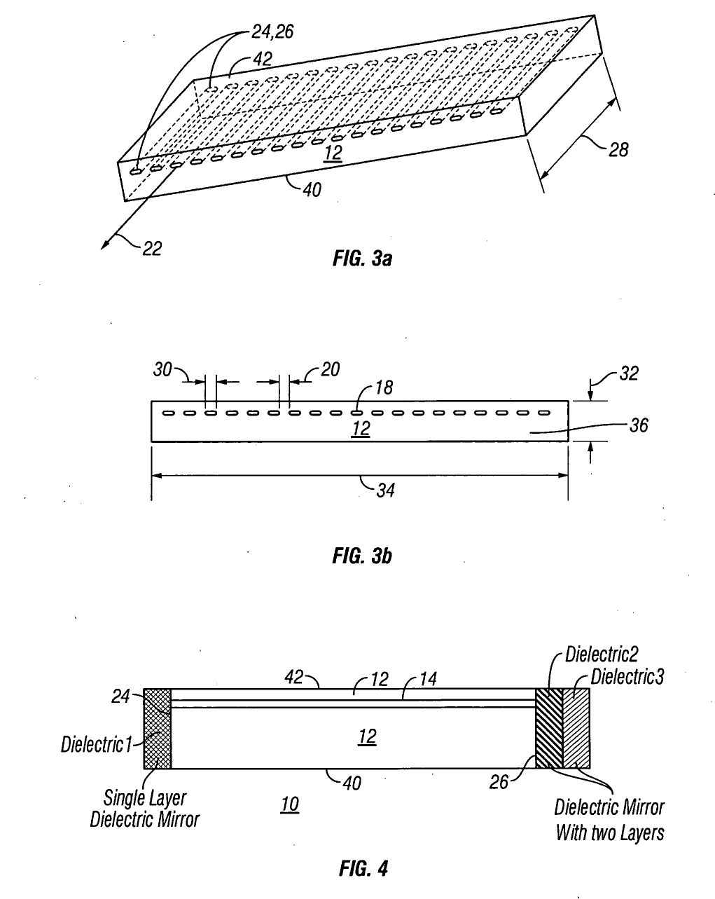

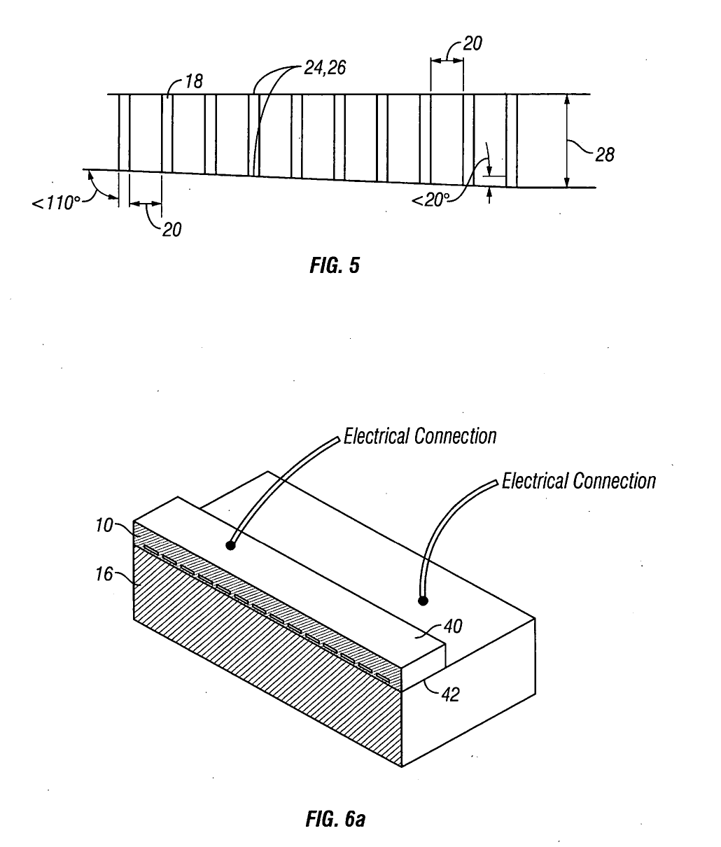

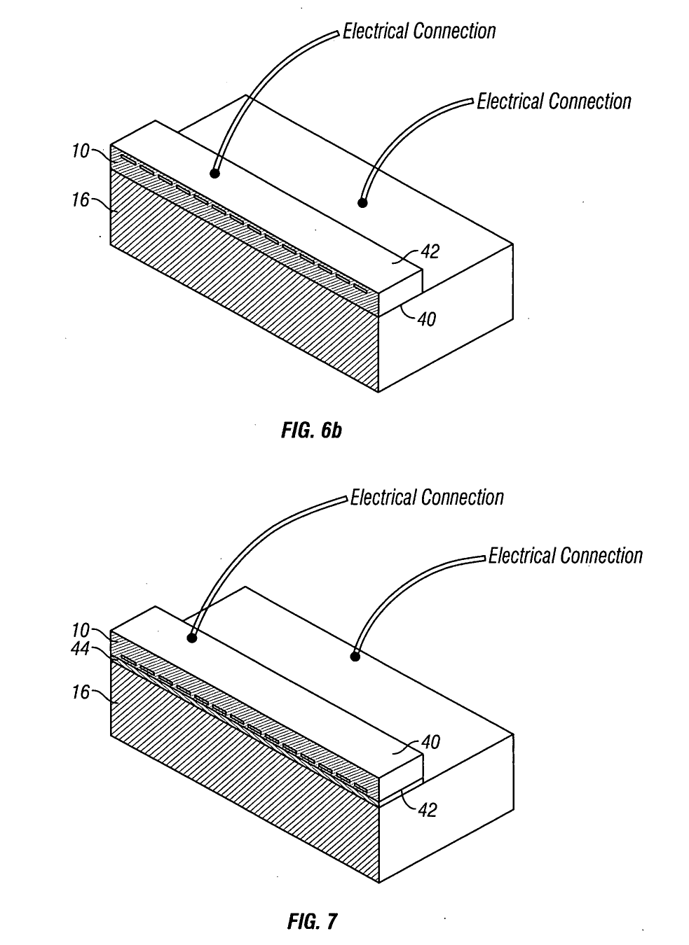

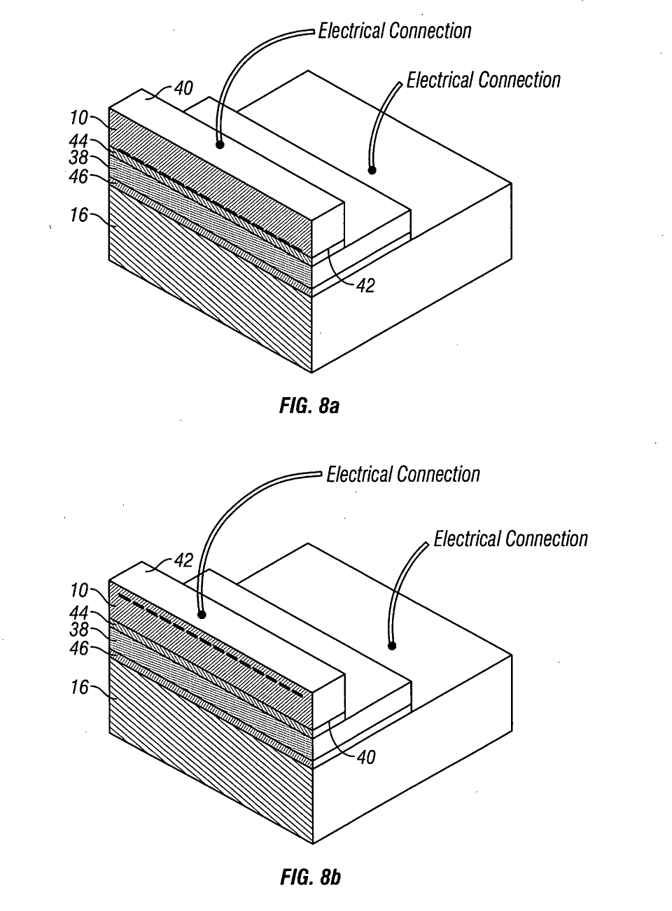

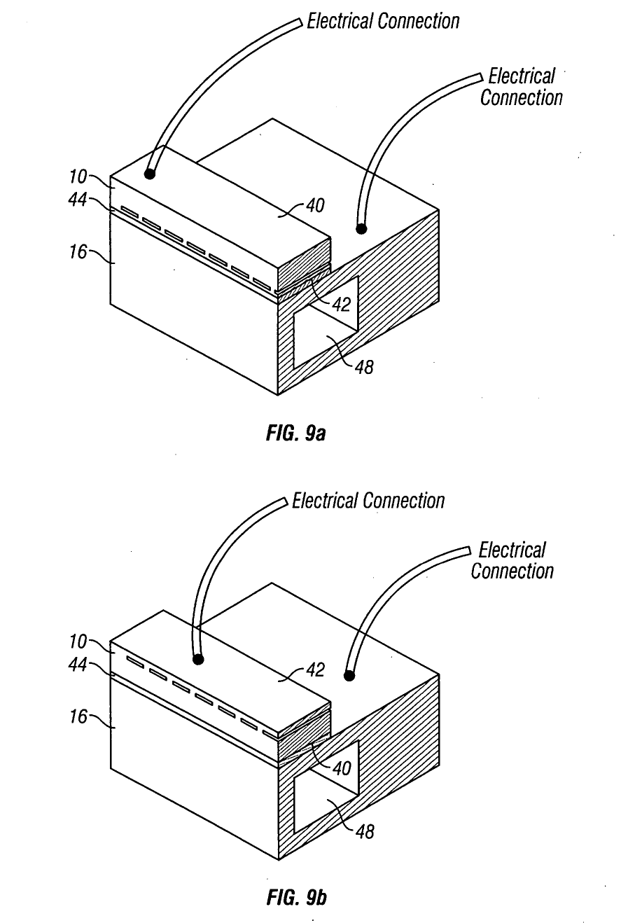

Referring to FIGS. 3(a) through 9(d), various embodiments of the present a laser diode array, generally denoted as 10, of the present invention, are illustrated. In one embodiment, laser diode array 10 includes a layered semiconductor structure 12 with at least one active layer 14. A heat sink 16 is coupled to layered semiconductor structure 12. A plurality of laser emitters 18 are formed in the at least one active layer 14. Laser emitters 18 each have a spacing 20 that is selected to provide for a more uniform heat distribution. In one embodiment, laser diode array 10 produces an output beam 22.

Emitters 18 can be spatially confined and localized lasers inside layered semiconductor structure 12 and includes laser mirrors. The laser mirrors are defined by two crystal mirror facets 24 and 26. The distance between crystal mirror facets 24 and 26 is the cavity length 28 of the laser, which can define one dimension of laser diode array 10. Each laser emits radiation from at least one crystal mirror facet 24 or 26. Each laser is further defined by its emitter width 30, which is a dimension perpendicular to the direction of the cavity length 28. The laser is further defined by it's the array height 32, which is a dimension perpendicular to the direction of the cavity length 28 and perpendicular to the direction of the emitter width 30.

Laser emitters 18 can each be in a transverse single mode and longitudinal multi mode but are not limited to such combination of transverse and longitudinal modes. Other such possible operation of laser emitters 18 can be in transverse and longitudinal single mode and in transverse and longitudinal multimode. Any number of laser emitters 18 can be provided.

The dimensions of laser diode array 10 can vary. Examples of suitable dimensions include but are not limited to, 10 mm×1.3 mm×0.14 mm. In one embodiment, laser diode array 10 has a width 34 and an emitter width 30 generally greater than 100 μm, cavity length 28 is greater than 100 μm and array height 32 is greater than 50 μm.

By way of illustration, in one specific embodiment, 400 laser emitters 18 can be used on a 10 mm wide laser diode array 10. Each laser emitter 18 can generate at least 1 mW optical power, depending upon emission wavelength and semiconductor material system. The output power of such 10 mm wide laser diode array 10 can be in the range of 0.4 W to greater 400 W. In another specific embodiment 100 laser emitters 18 can be used on a laser diode array 10 with a width 34 of 10 mm. Each laser emitter 18 can generate at least 10 mW optical power, depending upon emission wavelength and semiconductor material system. The output power of such a 10 mm wide laser diode array 10 can be in the range of 1 W to greater 1000 W. In yet another specific embodiment 150 laser emitters 18 can be used on a diode array 10 with a width 34 of 10 mm. Each can generate at least 5 mW of optical power, depending upon emission wavelength and semiconductor material system. The output power of such a 10 mm wide laser diode array 10 can be in the range of 0.75 W to greater 1500 W.

Spacing 20 is selected to no greater than 100 μm to provide more uniform heat dissipation. In other embodiments, spacing 20 is no greater than 90 μm, 80 μm, 70 μm, 60 μm and 50 μm. A closer emitter spacing 20, of no greater than 100 μm, raises the temperature of layered semiconductor structure 12 that is under non-emitter areas 36, which do not contribute to heat generation but aid in heat removal from laser emitters 18. A closer emitter spacing 20 enables increasing the number of laser emitters 18 of a laser array 10, thus reducing laser emitter width 30 and laser emitter 18 operating power density for a given operating power, thus reducing overall heat generation in laser emitter 18, reducing maximum center zone temperature and also reducing temperature differential across laser emitter 18. Compared to industry standard diode laser arrays, with 19 to 37 elements and laser emitter spacing greater than 150 μm, laser diode array 10, with spacing 20 of no greater than 100 μm, distributes the heat generated by laser emitters 18 more uniformly and reduces the temperature differential between laser emitter center and edge and related stress and strain across laser diode array 10.

Heat uniformity of laser diode array 10 can be improved by reducing the temperature differential across each laser emitter 18 compared to an industry standard laser diode array with 19 emitters. Table 1 lists respective values for temperature differentials. By way of example, and without limitation, in one embodiment, laser diode array 10, has 400 laser emitters 18, and reduces the respective temperature differential by 97%, from ˜2.6° C. for the standard 19 emitter array to ˜0.08° C. for the 400 laser emitter laser diode array 10 at 40 W laser array optical power.

TABLE 1

| | Emitter | | Emitter | | Temperature | | Wavelength |
|---|---|---|---|---|---|---|---|
| Number of | width | | spacing | | differential | | broadening for |
| Emitters | 30 | | 20 | | across emitter | | AlInGaAs |
| 19 | 135 | μm | 365 | μm | 2.6° | C. | 0.78 nm |
| 25 | 200 | μm | 200 | μm | 1.54° | C. | 0.46 nm |
| 50 | 100 | μm | 100 | μm | 0.77° | C. | 0.23 nm |
| 100 | 50 | μm | 50 | μm | 0.39° | C. | 0.12 nm |
| 250 | 20 | μm | 20 | μm | 0.15° | C. | 0.05 nm |
| 400 | 5 | μm | 20 | μm | 0.08° | C. | 0.02 nm |

Focusability of the laser emission of each laser emitter 18 of a laser diode array 10 with 400 laser emitters 18 can be improved by making the laser emitter width 30 narrow enough to force transverse single mode operation from each laser emitter 18. This enables diffraction limited spot sizes of a focused beam. By example, comparing this laser diode array 10 with single transverse mode laser emitters 18 to an industry standard 19 element laser diode array with 135 μm wide emitters, which has more than 10 transverse modes lasing, the minimum spot size is improved by at least a factor of 10.

The beam quality of output beam 22 is improved by providing more laser emitters 18 which are spaced closer than 100 μm. This improves homogeneity of laser diode array 10 emission across its width of all laser emitters 18 by lowering the peak output power per laser emitter 18 and reduces laser emitter width 30 of non lasing, dark, areas between laser emitters 18. By way of illustration, and without limitation, defining a figure of merit H for beam homogeneity across laser diode array 10 as peak laser emitter power [W] multiplied by laser emitter 18 to laser emitter 18 spacing [μm] 20, an industry standard 19 element laser diode array, with an emitter spacing of 365 μm and a width of 135 μm, has an H of 768 [Wμm] at 40 W power. By way of illustration, and without limitation, laser diode array 10, with 100 micron laser emitter spacing 20, 66 laser emitters each 50 μm wide, can improve homogeneity by 92% to 61 [Wμm], at the same power of 40 W. Smaller H factors indicate better beam homogeneity.

The spectral quality of beam 22 can be improved by lowering the temperature differential across each laser emitter 18. Closer spacing 20 than 100 μm, of more laser emitters 18, lowers the peak power per laser emitter 18, and lowers the temperature differential across laser emitter 18 and its related spectral broadening at a given operating power. Spectral broadening scales directly with the laser emitter 18 center to edge temperature differential. Each of the different laser materials has a different thermal shift of its emission wavelength with temperature. By way of example, and without limitation, comparing a 19 element industry standard laser array at 40 W with a laser diode array 10 with 400 laser emitters 18, reduces the respective temperature differential from ˜2.6° C. for the 19 emitter laser diode array to ˜0.08° C. for the 400 laser emitter laser diode array 10. Spectral broadening is reduced by 97% from 0.8 nm to 0.02 nm, with a laser diode array 10, which can be made from AlInGaAs, and has a typical thermal wavelength shift of its emission wavelength of 0.3 nm/° C.

Reliability of a laser diode array 10, coupled such as by soldering to a suitable heat sink 16, is improved, compared to industry standard 19 to 37 emitter laser arrays, by utilizing a larger number of laser emitters 18 spaced more closely than 100 μm. Assuming the same operating power level and typical distribution of solder voids across the soldered surface of laser diode array 10, solder void created hot spots under a laser laser emitter 18 can reduce laser diode array 10 power by a smaller amount because each laser emitter 18 operates at a lower power level. Statistically, this improves reliability for laser diode array 10, which can be mounted to a suitable heat sink 16, by a ratio of the size of laser emitters 18. By way of example, and without limitation, comparing an industry standard 10 mm, 19 emitter diode laser array with a laser diode array 10 with 400 5 μm laser emitters 18, at 40 W power levels, loss of a single laser emitter 18 reduces power loss from 2.1 W, 5.25%, for the 19 emitter laser diode array to 0.1 W, 0.25%, for the 400 laser emitter laser diode array 10. The ratio of laser emitters 18 can improve reliability by a factor of 27 (135/5) respectively.

In one embodiment a thermally expansion-matched submount 38 is used for bonding n-doped or p-doped, metallized surfaces 40 and 42 of laser diode array 10 for heat removal and for electrical contacting, and specifically to prevent breakage of laser diode array 10 from thermally induced stress which can be caused by a substantial mismatch of thermal expansion coefficients, greater than 50%, between laser diode array 10 and heat sink 16. Bonding of laser diode array 10 to submount 38 can be achieved by metal or alloy solders 44 which typically have a melting point below the melting point of the respective material of layered semiconductor structure 12. Suitable metal or alloy solders include but are not limited to Indium metal, AuSn, PbSn, AgSn, InAu alloys, and the like. The thermally expansion matched submount 38 can then be bonded to the surface of heat sink 16 by using similar metal or alloy solders 46. Suitable metal or alloy solders include Indium metal, AuSn, PbSn, AgSn, CuSil, and the like. Examples of suitable expansion-matched carriers 26 include but are not limited to, CuW compositions, AlN, BeO, Diamond-Copper, Diamond, Diamond like films, Sapphire and Silicon, for GaAs, InP or GaN semiconductor materials, and the like.

In accordance with one embodiment, the use of a thermally expansion matched submount 38 allows the use of hard solder alloys such as AuSn which offers significantly higher mechanical stability than Indium metal and prevents fatiguing and shearing of the bond between laser diode array 10 and its submount 38 and heat sink 16 during operation, thus improving reliability of the mounted laser diode array 10 in all practical applications. In addition, submount 38 can be pre-soldered to heat sink 16 with a mechanically very strong solder such as CuSil if the surface of heat sink 16 is made from copper or if it is plated with nickel. This solder provides the additional benefit of very high thermal and electrical conductivity.

In another embodiment, the metallized n-type or p-type surfaces 40 and 42 respectively, of laser diode array 10 can be directly soldered to the surface of heat sink 16 by using a soft metal 44, including but not limited to Indium solder. The surface of heat sink 16 can be any metal or ceramic. Heat sink 16 can be solid or configured for internal circulation of a liquid. The soft metal Indium solder compensates for substantially different thermal expansion of the surface of heat sink 16 and the material used for layer semiconductor structure 12.

FIG. 9(a) illustrates one embodiment of the present invention where layered semiconductor structure 12 is coupled with p-doped metallized surface 42 to a heat sink 16 that has a cooling channel 48. FIG. 9(b) illustrates one embodiment of the present invention where layered semiconductor structure 12 is coupled with n-doped metallized surface 40 to a heat sink 16 that has a cooling channel 48.

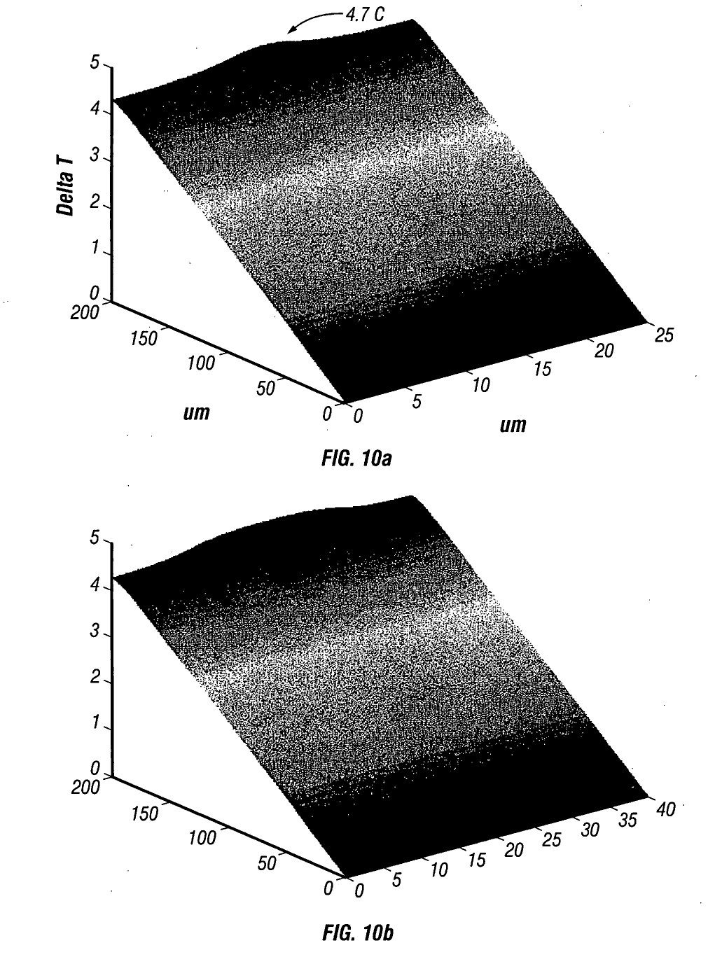

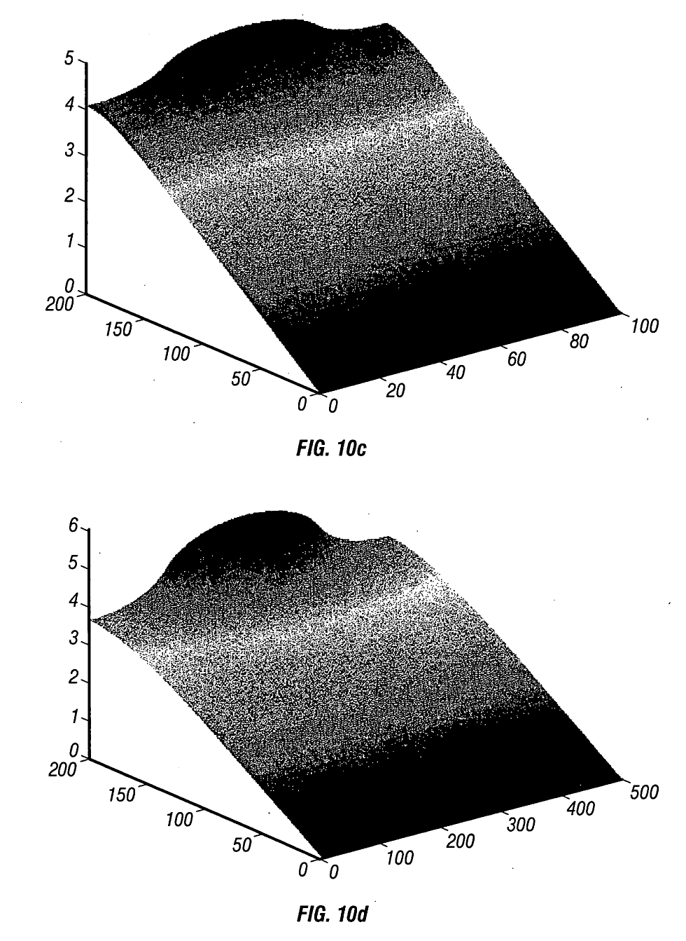

By way of illustration, and without limitation, FIGS. 10(a) through 10(d) illustrate temperature profiles across emitters 18 at 40 W of different embodiments of diode laser array 10. In FIG. 10(a), laser diode array 10 has 400 emitters 18 with an emitter width 30 of 5 μm and an emitter spacing 20 of 20 μm. In FIG. 10(b), laser diode array 10 has 250 emitters 18 with an emitter width 30 of 20 μm and an emitter spacing 20 of 20 μm. In FIG. 10(c), laser diode array 10 has 100 emitters 18 with an emitter width 30 of 50 μm and an emitter spacing 20 of 50 μm. In FIG. 10(d), laser diode array 10 has 50 emitters 18 with an emitter width 30 of 100 μm and an emitter spacing 20 of 100 μm.

In comparison, FIG. 2 illustrates a temperature profile for a standard laser diode array, commercially available from Spectra-Physics Lasers, Mountain View, Calif., with 19 emitters, that has an emitter width of 135 μm, and an emitter spacing of 365 μm. In the embodiments illustrated in FIGS. 10(a) through 10(d), heat sink 16 has a temperature of about 25° C. It will be appreciated that laser diode array 10 is not limited to the examples illustrated in FIGS. 10(a) through 10(d).

In various embodiments, laser array 10 can be utilized in a variety of applications including but not limited to, (i) pumping of solid state lasers and direct applications of output beam 22 for cutting, welding, soldering and processing of dead materials such as plastics, metals, wood and composites, (ii) use of output beam 22 in human medicine such as treatment of living organic tissue including s human organs, skin, the eye and the like, as well as for analytical, diagnostic purposes in determination of illnesses, (iii) printing, where higher resolution and higher speed presses require smaller spot sizes and larger depth of focus from a plurality of laser emitters 18, and the like.

Laser diode array 10 provides improved heat uniformity, beam homogeneity and narrower spectral emission line width, as well as array reliability as a result of smaller impact of a failing narrow laser emitter 18. Suitable materials for layered semiconductor structure 12 include but are not limited to, GaN, GaAs and InP based III-V semiconductors such as AlGaN, GaN, InGaN, InGaP, AlInGaP, AlGaAs, AlInGaAs, InGaAsP, InGaAs, InP, covering the wavelengths longer than 200 nm, and the like.

The foregoing description of a preferred embodiment of the invention has been presented for purposes of illustration and description. It is not intended to be exhaustive or to limit the invention to the precise forms disclosed. Obviously, many modifications and variations will be apparent to practitioners skilled in this art. It is intended that the scope of the invention be defined by the following claims and their equivalents.

1. A laser diode array, comprising:
a semiconductor layered structure including at least one active layer;
a heat sink coupled to semiconductor layered structure; and
a plurality of laser emitters formed in the active layer, a majority of the plurality of laser emitters having a spacing between adjacent laser emitters that provides for a more uniform heat distribution.

2. The of claim 1, wherein the spacing is the distance between adjacent laser emitters.

3. The array of claim 1, wherein the laser emitters are arranged as a linear array.

4. The array of claim 1, wherein at least a portion of the plurality of laser emitters include a crystal mirror facet.

5. The array of claim 4, wherein the at least a portion of the plurality of laser emitters that include a crystal mirror facet that includes at least one group III element.

6. The array of claim 4, wherein at least a portion of the crystal mirror facets is covered with at least one layer of dielectric material to form a laser mirror.

7. The array of claim 6, wherein the dielectric material is selected from the group Al₂O₃, SiO₂, Silicon, Germanium, Ta₂O₅, HfO₂, Ti₂O₅, Sc₂O₃, Nb₂O₅, AlN, Si₃N₄, InN, GaN and oxi-nitrides of Aluminum, Indium, Gallium, Silicon, Tantalum, Hafnium, Scandium and Titanium and Niobium

8. The array of claim 4, wherein at least a portion of crystal mirror facets is covered with at least two layers of a dielectric material.

9. The array of claim 8, wherein the at least two layers of dielectric material are selected from one or more of Al₂O₃, SiO₂, Silicon, Germanium, Ta₂O₅, HfO₂, Ti₂O₅, Sc₂O₃, Nb₂O₅, AlN, Si₃N₄, InN, GaN and oxi-nitrides of Aluminum, Indium, Gallium, Silicon, Tantalum, Hafnium, Scandium, Titanium and Niobium

10. The array of claim 1, wherein the more uniform heat distribution provides for reduced heat induced strain and stress between the semiconductor and the heat sink.

11. The array of claim 1, wherein the more uniform heat distribution provides for reduced heat induced strain in the at least one active layer.

12. The array of claim 1, wherein the spacing between at least two adjacent laser emitters is no greater than 100 microns.

13. The array of claim 1, wherein the spacing between at least two adjacent laser emitters is no greater than 90 microns.

14. The array of claim 1, wherein the spacing between at least two adjacent laser emitters is no greater than 80 microns.

15. The array of claim 1, wherein the spacing between at least two adjacent laser emitters is no greater than 70 microns.

16. The array of claim 1, wherein the spacing between at least two adjacent laser emitters is no greater than 60 microns.

17. The array of claim 1, wherein the spacing between at least two adjacent laser emitters is no greater than 50 microns.

18. The array of claim 1, wherein the array has a metallized n doped surface and a metallized p doped surface that is metallized at least at the location of the pluralty of laser emitters that is formed in the active layer.

19. The array of claim 1, wherein a majority of the plurality of laser emitters have a laser emitter width of 1 micron to 250 microns.

20. The array of claim 19, wherein a plane of the width is parallel, to within 20%, relative to a direction of the spacing between adjacent laser emitters

21. The array of claim 1, wherein a majority of the plurality of laser emitters are transverse single mode and longitudinally multi-mode.

22. The array of claim 1, wherein a majority of the plurality of laser emitters are transverse single mode and longitudinally single mode.

23. The array of claim 1, wherein a majority of the plurality of laser emitters are transverse multi mode, and longitudinal multi mode.

24. The array of claim 1, wherein the array produces an output with a wavelength of at least 200 nm.

25. The array of claim 1, wherein the thin layer semiconductor material includes a III-V semiconductor material.

26. The array of claim 1, wherein the semiconductor material is selected from AlGaN, AlInGaP, AlGaAs, InGaAsP, InGaN, InGaP, AlInGaAs, InP, GaN, GaP, InGaAs, and GaAs.

27. The array of claim 18, wherein the n doped metallized surface is mounted to the heat sink that provides heat removal.

28. The array of claim 18, wherein the n doped metallized surface is mounted to the heat sink and coupled to an electrical connection.

29. The array of claim 18, wherein the p doped metallized surface is coupled to an electrical connection.

30. The array of claim 18, wherein the p doped metallized surface is mounted to the heat sink that provides heat removal.

31. The array of claim 18, wherein the p doped metallized surface is mounted to the heat sink and coupled to an electrical connection.

32. The array of claim 18, wherein the n doped metallized surface is coupled to an electrical connection.

33. The array of claim 18, further comprising:
a sub-mount positioned between the heat sink and the layered semiconductor structure.

34. The array of claim 33, wherein the sub-mount has a face with dimensions that are substantially the same as the metallized n doped surface.

35. The array of claim 33, wherein the sub-mount has a face with dimensions that are substantially the same as the metallized p doped surface.

36. The array of claim 33, wherein the submount has a face with dimensions larger than the metallized n-doped surface.

37. The array of claim 33, wherein the submount has a face with dimensions larger than the metallized p-doped surface.

38. The array of claim 33, wherein the submount has a thermal expansion coefficient that is at least 20% of a thermal expansion coefficient of the layered semiconductor structure.

39. The array of claim 33, wherein the submount is made of a material that provides heat conductivity.

40. The array of claim 33, wherein the submount is made of material that provides electrical conductivity.

41. The array of claim 33, where the submount is made of material that does not provide electrical conductivity.

42. The array of claim 33, wherein a first bonding agent is positioned between the submount and the layered semiconductor structure.

43. The array of claim 33, wherein a second bonding agent is positioned between submount and the heat sink.

44. The array of claim 42, wherein the first bonding agent is a metal or a solder.

45. The array of claim 42, wherein the first bonding agent is made of a material that has a melting point less than a melting point of the layered semiconductor structure.

46. The array of claim 42, wherein the first bonding agent is made of a material that provides heat conductivity.

47. The array of claim 42, wherein the first bonding agent is made of material that provides electrical conductivity.

48. The array of claim 43, where the second bonding agent is made of material that does not provide electrical conductivity.

49. The array of claim 43, wherein the second bonding agent is a metal or a solder.

50. The array of claim 43, wherein the second bonding agent is made of a material that provides heat conductivity.

51. The array of claim 43, wherein the second bonding agent is made of material that provides electrical conductivity.

52. The array of claim 1, further comprising:
a first bonding agent positioned between the heat sink and the layered semiconductor structure.

53. The array of claim 52, wherein the first bonding agent is a metal or a solder.

54. The array of claim 52, wherein the first bonding agent is made of a material that has a melting point less than a melting point of the layered semiconductor structure.

55. The array of claim 52, wherein the first bonding agent is made of a material that provides heat conductivity.

56. The array of claim 52, wherein the first bonding agent is made of material that provides electrical conductivity.

57. The array of claim 1, wherein the plurality of laser emitters are made from the at least one active layer of the semiconductor.

58. The array of claim 57, wherein the at least one active layer is positioned between waveguide layers of the semiconductor.

59. The array of claim 1, wherein the heat sink is a material selected from, metal, metal containing composition, ceramic, carbide, glass, crystalline material and a semiconductor material.

60. The array of claim 33, wherein the heat sink is a material selected from, metal, metal containing composition, ceramic, carbide, glass, crystalline material and a semiconductor material.

61. The array of claim 48, wherein the heat sink is a material selected from, metal, metal containing composition, ceramic, carbide, glass, crystalline material and a semiconductor material.

62. The array of claim 1, wherein the heat sink includes channels configured to receive a cooling medium.

63. The array of claim 33, wherein the heat sink includes channels configured to receive a cooling medium.

64. The array of claim 48, wherein the heat sink includes channels configured to receive a cooling medium.

65. The array of claim 1, wherein the heat sink is optically contacted to the layered semiconductor structure.

66. The array of claim 1, wherein the heat sink is diffusion bonded to the layered semiconductor structure.

67. The array of claim 1, wherein the array is operated continuous wave (cw).

68. The array of claim 1, wherein the array is operated pulsed.

69. The array of claim 1, wherein the array produces a pulsed output with pulse widths of at least 100 micro seconds and duty cycles of less than 100%.

70. The array of claim 1, wherein the array is operated quasi-cw.

71. The array of claim 1, wherein the array produces a quasi cw output with pulse widths of less than 100 micro seconds and duty cycles of less than 100%.

72. A laser diode array, comprising:
a layered semiconductor structure with at least one active layer;
a heat sink coupled to the layered semiconductor structure; and
a plurality of laser emitters formed in the at least one active layer, at least a portion of the plurality of laser emitters having a spacing between adjacent laser emitters that is no greater than 50 microns.

73. The array of claim 72, wherein the plurality of laser emitters are arranged as a linear array.

74. The array of claim 72, wherein at least a portion of the plurality of laser emitters include a crystal mirror facet.

75. The array of claim 72, wherein the at least a portion of the plurality of laser emitters that includes a crystal mirror facet that includes at least one group III element.

76. The array of claim 74, wherein at least a portion of the crystal mirror facets is covered with at least one layer of dielectric material to form a laser mirror.

77. The array of claim 74, wherein at least a portion of crystal mirror facets is covered with at least two layers of a dielectric material.

78. The array of claim 72, wherein the array has a metallized n doped surface and a metallized p doped surface that is metallized at least at the location of the emitter that is formed in the active layer.

79. The array of claim 72, wherein a majority of the plurality of laser emitters have a laser emitter width of 1 micron to 250 microns.

80. The array of claim 79, wherein a plane of the width is parallel, to within 20%, relative to a direction of the spacing between adjacent emitters

81. The array of claim 72, wherein a majority of the plurality of laser emitters are transverse single mode and longitudinally multi-mode.

82. The array of claim 72, wherein a majority of the plurality of laser emitters are transverse single mode and longitudinally single mode.

83. The array of claim 72, wherein a majority of the plurality of laser emitters are transverse multi mode, and longitudinal multi mode.

84. The array of claim 72, wherein the array produces an output with a wavelength of at least 200 nm.

85. The array of claim 72, wherein the semiconductor material includes a III-V semiconductor material.

86. The array of claim 72, wherein the semiconductor material is selected from AlGaN, AlInGaP, AlGaAs, InGaAsP, InGaN, InGaP, AlInGaAs, InP, GaN, GaP, InGaAs, and GaAs.

87. The array of claim 78, wherein the n doped metallized surface is mounted to the heat sink that provides heat removal.

88. The array of claim 78, wherein the n doped metallized surface is mounted to the heat sink and coupled to an electrical connection.

89. The array of claim 78, wherein the p doped metallized surface is coupled to an electrical connection.

90. The array of claim 78, wherein the p doped metallized surface is mounted to the heat sink that provides heat removal.

91. The array of claim 78, wherein the p doped metallized surface is mounted to the heat sink and coupled to an electrical connection.

92. The array of claim 78, wherein the n doped metallized surface is coupled to an electrical connection.

93. The array of claim 78, further comprising:
a sub-mount positioned between the heat sink and the layered semiconductor structure.

94. The array of claim 93, wherein the sub-mount has a face with dimensions that are substantially the same as the metallized n doped surface.

95. The array of claim 93, wherein the submount has a face with dimensions larger than the metallized n-doped surface.

96. The array of claim 93, wherein the sub-mount has a face with dimensions that are substantially the same as the metallized p doped surface.

97. The array of claim 93, wherein the submount has a face with dimensions larger than the metallized p-doped surface.

98. The array of claim 93, wherein the submount has a thermal expansion coefficient that is at least 20% of a thermal expansion coefficient of the layered semiconductor structure.

99. The array of claim 93, wherein the submount is made of a material that provides heat conductivity.

100. The array of claim 93, wherein the submount is made of material that provides electrical conductivity.

101. The array of claim 93, where the submount is made of material that does not provide electrical conductivity.

102. The array of claim 93, wherein a first bonding agent is positioned between the submount and the layered semiconductor structure.

103. The array of claim 93, wherein a second bonding agent is positioned between submount and the heat sink.

104. The array of claim 72, further comprising:
a first bonding agent positioned between the heat sink and the layered semiconductor structure.

105. The array of claim 72, wherein the plurality of laser emitters are made from at least one active layer of the semiconductor.

106. The array of claim 105, wherein the active layers are positioned between waveguide layers of the semiconductor.

107. The array of claim 72, wherein the array is operated continuous wave (cw).

108. The array of claim 72, wherein the array is operated pulsed.

109. The array of claim 72, wherein the array produces a pulsed output with pulse widths of at least 100 micro seconds and duty cycles of less than 100%.

110. The array of claim 72, wherein the array is operated quasi-cw.

111. The array of claim 72, wherein the array produces a quasi cw output with pulse widths of less than 100 micro seconds and duty cycles of less than 100%.%

112. A method of producing a output from a laser diode array, comprising:
providing a laser diode array that has a layered semiconductor structure with at least one active layer and a plurality of laser emitters formed in the at least one active layer;
providing a spacing for at least a portion of the adjacent laser emitters to create a more uniform heat distribution.
removing heat from the semiconductor with a heatsink; and
producing an output beam

113. The method of claim 1 12, wherein the spacing between at least two adjacent laser emitters is no greater than 100 microns.

114. The method of claim 112, wherein the spacing between at least two adjacent laser emitters is no greater than 90 microns.

115. The method of claim 112, wherein the spacing between at least two adjacent laser emitters is no greater than 80 microns.

116. The method of claim 112, wherein the spacing between at least two adjacent laser emitters is no greater than 70 microns.

117. The method of claim 112, wherein the spacing between at least two adjacent laser emitters is no greater than 60 microns.

118. The method of claim 112, wherein the spacing between at least two adjacent laser emitters is no greater than 50 microns.

119. The method of claim 112, wherein the more uniform heat distribution provides for reduced heat induced strain and stress between the semiconductor and the heat sink.

120. The method of claim 112, wherein the more uniform heat distribution provides for reduced heat induced strain in the at least one active layer.

121. The method of claim 112, wherein the output has a wavelength of at least 200 nm.

122. The method of claim 112, wherein the output is a pulsed output.

123. The method of claim 112, wherein the output is pulsed with pulse widths of at least 100 micro seconds and duty cycles of less than 100%.

124. The method of claim 112, wherein the output as a quasi-cw output.

125. The method of claim 112, wherein the output is a quasi cw output with pulse widths of less than 100 micro seconds and duty cycles of less than 100%.
